(19) United States
(12) Patent Application Publication
(10) Pub. No.: US 2015/0029428 A1
(43) Pub. Date: Jan. 29, 2015

(54) COLOR FILTER SUBSTRATE, MANUFACTURING PROCESS THEREOF AND LIQUID CRYSTAL DISPLAY PANEL

(71) Applicants: Wuhan Tianma Micro-Electronics Co., Ltd., Wuhan (CN); TIANMA MICRO-ELECTRONICS CO., LTD., Shenzhen (CN)

(72) Inventors: Nahong WANG, Wuhan (CN); Chao Dai, Wuhan (CN)

(73) Assignees: Wuhan Tianma Micro-Electronics Co., Ltd., Shenzhen (CN); TIANMA MICRO-ELECTRONICS CO., LTD., Shenzhen (CN)

(21) Appl. No.: 14/288,404

(22) Filed: May 28, 2014

(30) Foreign Application Priority Data
Jul. 29, 2013 (CN) 201310322108.8

(51) Int. Cl. G02F 1/1335; G02B 5/20; G03F 7/00; G02F 1/1362

(52) U.S. Cl. CPC G02F 1/133516; G02F 1/1362; G02B 5/20; G03F 7/0007; G02F 2001/136222
USPC 349/42; 359/885; 430/7

(57) ABSTRACT

Embodiments of the present invention provide a color filter substrate, a liquid crystal display panel including the color filter substrate, and a manufacturing process of the color filter substrate. The color filter substrate provided in the present invention includes: a substrate, including a display area and a non-display area on the periphery of the display area; and a black matrix, disposed on the substrate, wherein the black matrix in the display area on the substrate defines sub-pixels area, and the black matrix corresponding to the non-display area on the substrate includes a non-flat surface.

### BACKGROUND OF THE INVENTION

Flat-panel displays are mainstream displays at present, wherein liquid crystal displays are widely applied to electronic products such as computer screens, mobile phones, personal digital assistants, and flat-screen televisions due to the advantages of lightweight, thinness, power saving, no radiation and the like.

A liquid crystal display includes a liquid crystal display panel, and the liquid crystal display panel generally includes a thin film transistor array substrate, a color filter substrate, and a liquid crystal sealed between the two substrates. FIG. 1 is a schematic diagram of a partial cross-section of a liquid crystal display panel put forward in the related art. As shown in FIG. 1, the liquid crystal display panel 1 mainly includes a thin film transistor array substrate 2, a color filter substrate 3 opposite to the thin film transistor array substrate 2, a sealant 4 for bonding and curing the thin film transistor array substrate 2 and the color filter substrate 3, and liquid crystal sealed between the two substrates, wherein the color filter substrate 3 also includes a substrate 7, a black matrix 8, and a color filter pattern 9, and part of the color filter substrate 3 also includes a common electrode layer 6. In the related art, the sealant 4 is generally coated above the black matrix 8 outside a display area.

As a part of the manufacturing process, the LCD goes through one or more testing processes. While conventional systems and techniques exist, they are often inadequate as explained below. It is desirable to have improved systems and methods for manufacturing LCDs.

### BRIEF DESCRIPTION OF THE DRAWINGS

FIG. 1 is a simplified schematic diagram of a local section of a liquid crystal display panel in the related art;

FIG. 2 is a simplified schematic diagram of a local section of a liquid crystal display panel including a color filter substrate where a protrusion is disposed on the surface of a black matrix in a non-display area in an embodiment of the present invention;

FIG. 3 is a simplified schematic diagram of a local section of a liquid crystal display panel including a color filter substrate where a groove is disposed on the surface of a black matrix in a non-display area in another embodiment of the present invention;

FIG. 4 is a simplified schematic diagram of a local section of a liquid crystal display panel including a color filter substrate where multiple protrusions are disposed on the surface of a black matrix in a non-display area in another embodiment of the present invention;

FIG. 5 is a simplified schematic diagram of a local section of a liquid crystal display panel including a color filter substrate where multiple grooves are disposed on the surface of a black matrix in a non-display area in another embodiment of the present invention;

FIG. 6 is a simplified schematic diagram of a local section of a liquid crystal display panel including a color filter substrate where protrusions and grooves are disposed on the surface of a black matrix in a non-display area in another embodiment of the present invention;

FIG. 7 is a simplified schematic diagram of a local section of a liquid crystal display panel including a color filter substrate where protrusions and grooves are disposed on the surface of a black matrix in a non-display area in another embodiment of the present invention;

FIG. 8 is simplified a schematic diagram of a manufacturing process for a color filter substrate where protrusions are disposed on the surface of a black matrix in a non-display area in another embodiment of the present invention;

FIG. 9 is a simplified schematic diagram of a manufacturing process for a color filter substrate where protrusions are disposed on the surface of a black matrix in a non-display area in another embodiment of the present invention;

FIG. 10 is a simplified schematic diagram of a manufacturing process for a color filter substrate where grooves are disposed on the surface of a black matrix in a non-display area in another embodiment of the present invention;

FIG. 11 is a simplified schematic diagram of a manufacturing process for a color filter substrate where grooves are disposed on the surface of a black matrix in a non-display area in another embodiment of the present invention.

### DETAILED DESCRIPTION OF THE INVENTION

Embodiments of the present invention provide a color filter substrate, including: a substrate including a display area and a non-display area on the periphery of the display area; a black matrix, disposed on the substrate, wherein the black matrix in the display area on the substrate defines sub-pixels area, and the black matrix corresponding to the non-display area on the substrate includes a non-flat surface; and a color filter pattern, disposed in the sub-pixels area.

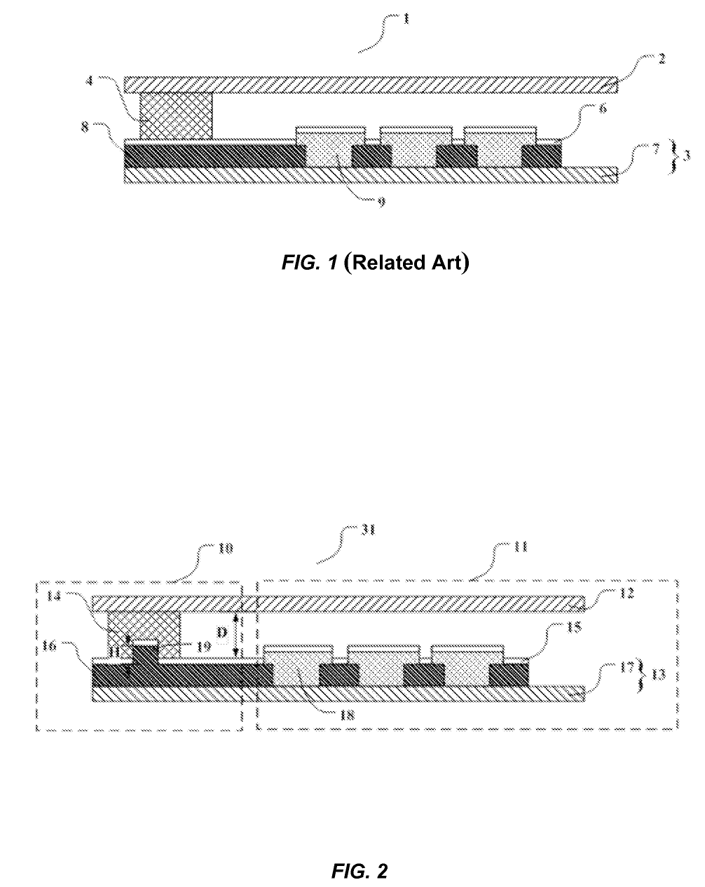

As explained above, it is desirable to new and improved systems and methods for LCD manufacturing. Now referring back to FIG. 1. After the liquid crystal display panel 1 is manufactured, peeling test is generally performed on the panel, to test whether the bonding of the sealant 4 is stable or not, so as to prevent the liquid crystal from leaking However, the peeling test result shows that the material difference between the common electrode layer 6 or the black matrix 8 and the sealant 4 is great, and the contact area between the sealant 4 and the common electrode layer 6 or the black matrix 8 is smaller and smaller with the trend that the frame of the liquid crystal display is narrower and narrower, so that the adhesive force between the color filter substrate 3 and the sealant 4 is smaller and smaller, the color filter substrate 3 and the sealant 4 are easy to peel to result in the problems of liquid crystal leakage and the like, the peeling test cannot meet the requirement, the quality of a product is affected, and the production efficiency is reduced. It is to be appreciated that embodiments of the present invention provide efficient methods for LCD manufacturing.

According to certain embodiments, the present invention also provides a liquid crystal display panel including the color filter substrate. The liquid crystal display panel includes a display area and a non-display area on the periphery of the display area. The liquid crystal display panel includes: the above-mentioned color filter substrate; a thin film transistor array substrate, disposed opposite to the color filter substrate; and a liquid crystal sealed between the color filter substrate and the thin film transistor array substrate.

In various embodiments, the present invention also provides a manufacturing process of the color filter substrate. The color filter substrate includes a display area and a non-display area on the periphery of the display area. A black matrix in the display area on the color filter substrate defines sub-pixels area. The black matrix in the non-display area on the color filter substrate includes a non-flat surface. A color filter pattern is disposed in the sub-pixels area. An manufacturing process includes the following steps:
1. providing a substrate;
2. forming a light-tight photoresist layer on the substrate, patterning the light-tight photoresist layer, forming a black matrix in a display area, defining sub-pixels area, and forming a black matrix with a non-flat surface in a non-display area at the same time; and
3. forming a color filter layer on the light-tight photoresist layer in the sub-pixels area.

To make the above-mentioned objectives, characteristics, and advantages of the present invention more obvious and easy to understand, the present invention is further described below in conjunction with the accompanying drawings and embodiments.

It should be noted that specific details are illustrated in the following descriptions to fully understand the present invention. However, the embodiments of the present invention may be implemented in multiple other modes different from the descriptions herein, and similar promotions may be made by those skilled in the art without departing from the contents of the present invention. Accordingly, the present invention is not limited to the specific embodiments disclosed below. Please refer to FIG. 2. FIG. 2 is a schematic diagram of a local section of a liquid crystal display panel including a color filter substrate where a protrusion is disposed on the surface of a black matrix in a non-display area in an embodiment of the present invention. As shown in FIG. 2, the present embodiment provides a liquid crystal display panel 31. The liquid crystal display panel 31 includes a display area 11 and a non-display area 10 on the periphery of the display area 11. The liquid crystal display panel specifically includes: a color filter substrate 13; a thin film transistor array substrate 12, disposed opposite to the color filter substrate 13; a liquid crystal (not shown in the figure) sealed between the color filter substrate 13 and the thin film transistor array substrate 12; and a sealant 14, disposed in the non-display area 10 of the liquid crystal display panel 31 and between the thin film transistor array substrate 12 and the color filter substrate 13.

The color filter substrate 13 includes: a substrate 17, which includes a display area 11 and a non-display area 10 on the periphery of the display area 11; a black matrix 16, disposed on the substrate 17, where the black matrix 16 in the display area 11 on the substrate 17 defines sub-pixels area, and a protrusion 19 is disposed on the surface of the black matrix 16 corresponding to the non-display area 10 on the substrate 17; a color filter pattern 18, disposed in the sub-pixels area defined by the black matrix in the display area 11; and an alignment layer (not shown in the figure).

The color filter substrate 13 also includes a common electrode layer 15 disposed on the black matrix 16 and the color filter pattern 18, but for an in-plane switching type liquid crystal display panel, a fringe-field switching liquid crystal display panel and the like, the common electrode layer does not need to be disposed on the color filter substrate. In a preferred embodiment, the common electrode layer 15 is disposed on the color filter substrate 13.

The protrusion 19 is disposed on the black matrix 16 corresponding to the non-display area 10 on the substrate 17. The height “H” of the highest possible position of the protrusion 19 may be smaller than or equal to the distance “D” between the color filter substrate 13 and the thin film transistor array substrate 12. In an embodiment, the height “H” of the highest position of the protrusion 19 is smaller than the distance “D” between the color filter substrate 13 and the thin film transistor array substrate 12. The protrusion 19 may be in any of a single island shape, an end-to-end connected continuous shape, and a combination of island shape and end-to-end connected continuous shape, and the specific structure of the protrusion 19 can be in other forms as well. The protrusion 19 may be spherical, conical, columnar, square, cubic, or in other irregular shapes, and the specific shape of the protrusion 19 is not limited in this embodiment.

The liquid crystal display panel 31 also includes the sealant 14 disposed between the thin film transistor array substrate 12 and the color filter substrate 13 and located in the non-display area 10. The unprocessed sealant is liquid, which is cured through ultraviolet after being filled in the whole sealant area of the non-display area 10 to form the sealant 14 with a groove. The groove is matched with the protrusion 19 disposed on the black matrix 16 in the non-display area 10.

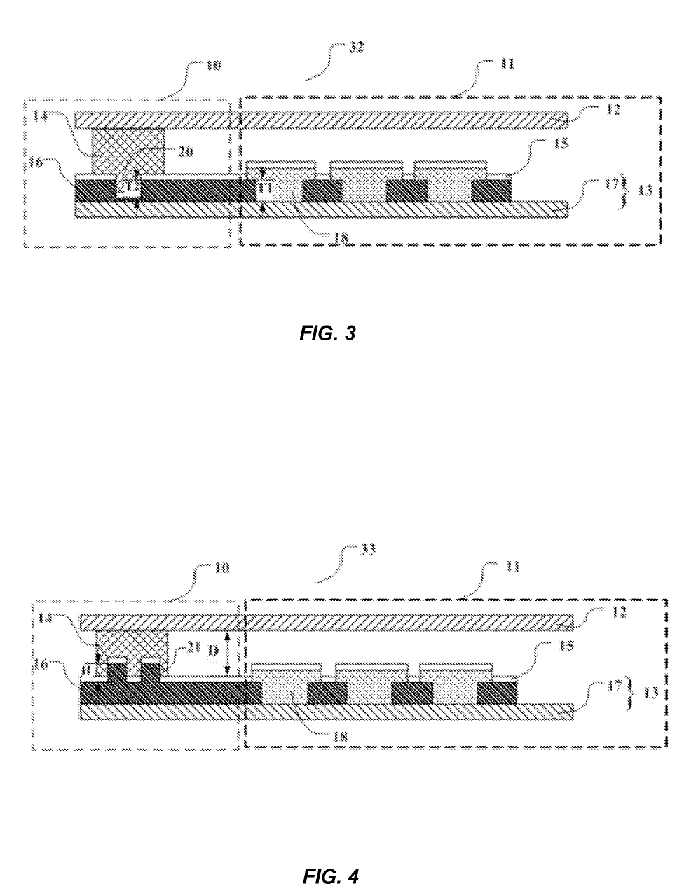

According to an embodiment, the protrusion 19 is disposed on the surface of the black matrix 16 on the color filter substrate 13, to enlarge the contact area between the color filter substrate 13 and the sealant 14, to improve the adhesive strength between the color filter substrate 13 and the sealant 14, and preferably, to enlarge the contact area between the color filter substrate 13 and the sealant 14, to change the shape of the contact surface between the color filter substrate 13 and the sealant 14, to increase the peeling strength of the color filter substrate 13 and the thin film transistor array substrate 12, and to avoid the problems of liquid crystal leakage and the like caused by the reason that the color filter substrate 13 and the sealant 14 are easy to peel at the same time. Please refer to FIG. 3. FIG. 3 is a schematic diagram of a local section of a liquid crystal display panel including a color filter substrate where a groove is disposed on the surface of a black matrix in a non-display area in another embodiment of the present invention. As shown in FIG. 3, certain embodiments of the present invention provide a liquid crystal display panel 32, which includes a display area 11 and a non-display area 10 on the periphery of the display area 11, and specifically includes: a color filter substrate 13; a thin film transistor array substrate 12, disposed opposite to the color filter substrate 13; a liquid crystal (not shown in the figure), sealed between the color filter substrate 13 and the thin film transistor array substrate 12; and a sealant 14, disposed in the non-display area 10 of the liquid crystal display panel 32 and between the thin film transistor array substrate 12 and the color filter substrate 13.

The color filter substrate 13 includes: a substrate 17, including a display area 11 and a non-display area 10 on the periphery of the display area 11; a black matrix 16, disposed on the substrate 17, wherein the black matrix 16 in the display area 11 on the substrate 17 defines sub-pixels area, and a groove 20 is disposed on the surface of the black matrix 16 corresponding to the non-display area 10 on the substrate 17; a color filter pattern 18, disposed in the sub-pixels area defined by the black matrix in the display area 11; and an alignment layer (not shown in the figure).

The color filter substrate 13 also includes a common electrode layer 15 disposed on the black matrix 16 and the color filter pattern 18, but for an in-plane switching type liquid crystal display panel, a fringe-field switching liquid crystal display panel and the like, the common electrode layer does not need to be disposed on the color filter substrate, and this embodiment in which the common electrode layer 15 is disposed on the color filter substrate 13 is a preferred embodiment.

The groove 20 is disposed on the black matrix 16 corresponding to the non-display area 10 on the substrate 17. The greatest longitudinal depth “T2” of the groove 20 may be smaller than or equal to the thickness “T1” of the black matrix 16, and preferably in this embodiment, is smaller than the thickness “T1” of the black matrix 16. The groove 20 may be in any of a single island shape, an end-to-end connected continuous shape, and a combination of island shape and end-to-end connected continuous shape, and the specific structure of the groove 20 is not limited in this embodiment. The groove 20 may be spherical, conical, columnar, square, cubic, or in other irregular shapes, and the specific shape of the groove 20 is not limited in this embodiment.

The liquid crystal display panel 32 also includes the sealant 14 disposed between the thin film transistor array substrate 12 and the color filter substrate 13, and located in the non-display area 10. The unprocessed sealant is liquid, which is cured through ultraviolet after being filled in the whole sealant area of the non-display area 10 to form the sealant 14 with a protrusion, and the protrusion is matched with the groove 20 disposed on the black matrix 16 in the non-display area 10.

The groove 20 is disposed on the surface of the black matrix 16 on the color filter substrate 13 of this embodiment, to enlarge the contact area between the color filter substrate 13 and the sealant 14, to improve the adhesive strength between the color filter substrate 13 and the sealant 14, and preferably, to enlarge the contact area between the color filter substrate 13 and the sealant 14, to change the shape of the contact surface between the color filter substrate 13 and the sealant 14, to increase the peeling strength of the color filter substrate 13 and the thin film transistor array substrate 12, and to eliminate the problems of liquid crystal leakage and the like caused by the reason that the color filter substrate 13 and the sealant 14 are easy to peel at the same time.

Please refer to FIG. 4. FIG. 4 is a simplified schematic diagram of a local section of a liquid crystal display panel including a color filter substrate, where multiple protrusions are disposed on the surface of a black matrix in a non-display area in an embodiment of the present invention. As shown in FIG. 4, the embodiment provides a liquid crystal display panel 33, which includes a display area 11 and a non-display area 10 on the periphery of the display area 11, and specifically includes: a color filter substrate 13; a thin film transistor array substrate 12, disposed opposite to the color filter substrate 13; a liquid crystal (not shown in the figure), sealed between the color filter substrate 13 and the thin film transistor array substrate 12; and a sealant 14, disposed in the non-display area 10 of the liquid crystal display panel 33 and between the thin film transistor array substrate 12 and the color filter substrate 13.

The color filter substrate 13 specifically includes: a substrate 17, including a display area 11 and a non-display area 10 on the periphery of the display area 11; a black matrix 16, disposed on the substrate 17, where the black matrix 16 in the display area 11 on the substrate 17 defines sub-pixels area, and two protrusions 21 are disposed on the surface of the black matrix 16 corresponding to the non-display area 10 on the substrate 17; a color filter pattern 18, disposed in the sub-pixels area defined by the black matrix in the display area 11; and an alignment layer (not shown in the figure).

The color filter substrate 13 also includes a common electrode layer 15 disposed on the black matrix 16 and the color filter pattern 18, but for an in-plane switching type liquid crystal display panel, a fringe-field switching liquid crystal display panel and the like, the common electrode layer does not need to be disposed on the color filter substrate, and this embodiment in which the common electrode layer 15 is disposed on the color filter substrate 13 is a preferred embodiment.

The two protrusions 21 are disposed on the black matrix 16 corresponding to the non-display area 10 on the substrate 17. Multiple protrusions 21 may also be disposed at equal intervals or disposed irregularly and may be equal or unequal in shape and size, and the specific arrangement mode and size of the multiple protrusions 21 are not limited in this embodiment. In consideration of the difficulty degree of manufacturing process, the protrusions 21 are disposed at equal intervals and are equal in shape and size in an exemplary embodiment, so as to simplify the manufacturing process and improve the production efficiency. The height “H” of the highest position of each protrusion 21 may be smaller than or equal to the distance “D” between the color filter substrate 13 and the thin film transistor array substrate 12, and preferably in this embodiment, is smaller than the distance “D” between the color filter substrate 13 and the thin film transistor array substrate 12. The protrusions 21 may be in a single island shape, an end-to-end connected continuous shape, and a combination of island shape and end-to-end connected continuous shape. The specific structure of the protrusions 21 can be in other shapes as well. The protrusions 21 may be spherical, conical, columnar, square, cubic, or in other irregular shapes, and the specific shape of the protrusions 21 is not limited in this embodiment.

The liquid crystal display panel 33 also includes the sealant 14 disposed between the thin film transistor array substrate 12 and the color filter substrate 13 and located in the non-display area 10. The unprocessed sealant is liquid, which is cured through ultraviolet after being filled in the whole sealant area of the non-display area 10 to form the sealant 14 with two grooves. Of course, the sealant 14 may also form multiple grooves, and the multiple grooves are matched with multiple protrusions 21 disposed on the black matrix 16 in the non-display area 10.

Multiple protrusions 21 are disposed on the surface of the black matrix 16 on the color filter substrate 13 of the present embodiment, to further enlarge the contact area between the color filter substrate 13 and the sealant 14, improve the adhesive strength between the color filter substrate 13 and the sealant 14, and more preferably, enlarge the contact area between the color filter substrate 13 and the sealant 14, change the shape of the contact surface between the color filter substrate 13 and the sealant 14, increase the peeling strength of the color filter substrate 13 and the thin film transistor array substrate 12, and avoid the problems of liquid crystal leakage and the like caused by the reason that the color filter substrate 13 and the sealant 14 are easy to peel at the same time.

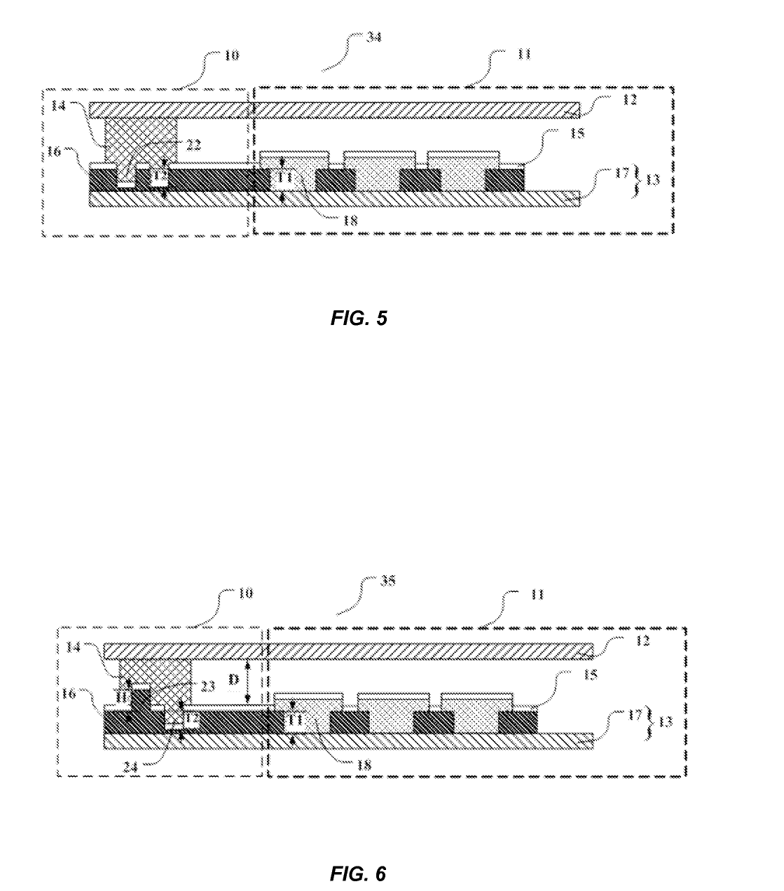

Please refer to FIG. 5. FIG. 5 is a simplified schematic diagram of a local section of a liquid crystal display panel including a color filter substrate where multiple grooves are disposed on the surface of a black matrix in a non-display area in another embodiment of the present invention. As shown in FIG. 5, the present embodiment provides a liquid crystal display panel 34, which includes a display area 11 and a non-display area 10 on the periphery of the display area 11, and specifically includes: a color filter substrate 13; a thin film transistor array substrate 12, disposed opposite to the color filter substrate 13; a liquid crystal (not shown in the figure), sealed between the color filter substrate 13 and the thin film transistor array substrate 12; and a sealant 14, disposed in the non-display area 10 of the liquid crystal display panel 34 and between the thin film transistor array substrate 12 and the color filter substrate 13.

The color filter substrate 13 specifically includes: a substrate 17, including a display area 11 and a non-display area 10 on the periphery of the display area 11; a black matrix 16, disposed on the substrate 17, wherein the black matrix 16 in the display area 11 on the substrate 17 defines sub-pixels area, and multiple grooves 22 are disposed on the surface of the black matrix 16 corresponding to the non-display area 10 on the substrate 17; a color filter pattern 18, disposed in the sub-pixels area defined by the black matrix in the display area 11; and an alignment layer (not shown in the figure).

The color filter substrate 13 also includes a common electrode layer 15 disposed on the black matrix 16 and the color filter pattern 18, but for an in-plane switching type liquid crystal display panel, a fringe-field switching liquid crystal display panel and the like, the common electrode layer does not need to be disposed on the color filter substrate, and this embodiment in which the common electrode layer 15 is disposed on the color filter substrate 13 is a preferred embodiment.

Two grooves 22 are disposed on the black matrix 16 corresponding to the non-display area 10 on the substrate 17. Of course, multiple grooves 22 may also be disposed, may be disposed at equal intervals or disposed irregularly and may be equal or unequal in shape and size, and the specific arrangement mode and size of the multiple grooves 22 are not limited in this embodiment. In consideration of the difficulty degree of manufacturing procedures, preferably, the grooves 22 are disposed at equal intervals and are equal in shape and size as an example in this embodiment, so as to simplify the manufacturing procedures and improve the production efficiency. The greatest longitudinal depth “T2” of each groove 22 is smaller than or equal to the thickness “T1” of the black matrix 16, and preferably in this embodiment, is smaller than the thickness “T1” of the black matrix 16. The grooves 22 may be in any of a single island shape, an end-to-end connected continuous shape, and a combination of island shape and end-to-end connected continuous shape, and the specific structure of the grooves 22 is not limited in this embodiment. The grooves 22 may be spherical, conical, columnar, square, cubic, or in other irregular shapes, and the specific shape of the grooves 22 is not limited in this embodiment.

The liquid crystal display panel 34 also includes the sealant 14 disposed between the thin film transistor array substrate 12 and the color filter substrate 13 and located in the non-display area 10. The unprocessed sealant is liquid, which is cured through ultraviolet after being filled in the whole sealant area of the non-display area 10 to form the sealant 14 with two protrusions. Of course, the sealant 14 may also form multiple protrusions, and the multiple protrusions are matched with the multiple grooves 22 disposed on the black matrix 16 in the non-display area 10.

The multiple grooves 22 are disposed on the surface of the black matrix 16 on the color filter substrate 13 of the present embodiment, to enlarge the contact area between the color filter substrate 13 and the sealant 14, improve the adhesive strength between the color filter substrate 13 and the sealant 14, and more preferably, enlarge the contact area between the color filter substrate 13 and the sealant 14, change the shape of the contact surface between the color filter substrate 13 and the sealant 14, increase the peeling strength of the color filter substrate 13 and the thin film transistor array substrate 12, and avoid the problems of liquid crystal leakage and the like caused by the reason that the color filter substrate 13 and the sealant 14 are easy to peel at the same time.

Please refer to FIG. 6. FIG. 6 is a simplified schematic diagram of a local section of a liquid crystal display panel including a color filter substrate where multiple protrusions and multiple grooves are disposed on the surface of a black matrix in a non-display area in another embodiment of the present invention. As shown in FIG. 6, the embodiment provides a liquid crystal display panel 35, which includes a display area 11 and a non-display area 10 on the periphery of the display area 11, and specifically includes: a color filter substrate 13; a thin film transistor array substrate 12, disposed opposite to the color filter substrate 13; a liquid crystal (not shown in the figure), sealed between the color filter substrate 13 and the thin film transistor array substrate 12; and a sealant 14, disposed in the non-display area 10 of the liquid crystal display panel 35 and between the thin film transistor array substrate 12 and the color filter substrate 13.

The color filter substrate 13 specifically includes: a substrate 17, including a display area 11 and a non-display area 10 on the periphery of the display area 11; a black matrix 16, disposed on the substrate 17, wherein the black matrix 16 in the display area 11 on the substrate 17 defines sub-pixels area, and multiple protrusions 23 and multiple grooves 24 are disposed on the surface of the black matrix 16 corresponding to the non-display area 10 on the substrate 17; a color filter pattern 18, disposed in the sub-pixels area defined by the black matrix in the display area 11; and an alignment layer (not shown in the figure).

The color filter substrate 13 also includes a common electrode layer 15 disposed on the black matrix 16 and the color filter pattern 18, but for a in-plane switching type liquid crystal display panel, a fringe-field switching liquid crystal display panel and the like, the common electrode layer does not need to be disposed on the color filter substrate, and this embodiment in which the common electrode layer 15 is disposed on the color filter substrate 13 is a preferred embodiment.

One protrusion 23 and one groove 24 are disposed on the black matrix 16 corresponding to the non-display area 10 on the substrate 17 in this embodiment. Multiple protrusions 23 and multiple grooves 24 may also be disposed at equal intervals or disposed irregularly and may be equal or unequal in shape and size, and the specific arrangement mode and size of the multiple protrusions 23 and the multiple grooves 24 are not limited in this embodiment. In consideration of the difficulty degree of manufacturing procedures, preferably, the multiple protrusions 23 and the multiple grooves 24 are disposed at equal intervals and are equal in shape and size as an example in this embodiment, so as to simplify the manufacturing procedures and improve the production efficiency. The height “H” of the highest position of each protrusion 23 may be smaller than or equal to the distance “D” between the color filter substrate 13 and the thin film transistor array substrate 12, and preferably in this embodiment, is smaller than the distance “D” between the color filter substrate 13 and the thin film transistor array substrate 12. The greatest longitudinal depth “T2” of each groove 24 is smaller than or equal to the thickness “T1” of the black matrix 16, and preferably in this embodiment, is smaller than the thickness “T1” of the black matrix 16. The protrusions 23 and the grooves 24 may be in any of a single island shape, an end-to-end connected continuous shape, and a combination of island shape and end-to-end connected continuous shape, and the specific structures of the protrusions 23 and the grooves 24 are not limited in this embodiment. The protrusions 23 and the grooves 24 may be spherical, conical, columnar, square, cubic, or in other irregular shapes, and the specific shapes of the protrusions 23 and the grooves 24 are not limited in this embodiment.

The liquid crystal display panel 35 also includes the sealant 14 disposed between the thin film transistor array substrate 12 and the color filter substrate 13 and located in the non-display area 10. The unprocessed sealant is liquid, and the liquid sealant is cured through ultraviolet after being filled in the whole sealant area of the non-display area 10 to form the sealant 14 with one protrusion and one groove. Of course, the sealant 14 may also form multiple grooves and multiple protrusions, in addition the multiple grooves and the multiple protrusions are matched with the multiple protrusions 23 and the multiple grooves 24 disposed on the black matrix 16 in the non-display area 10.

The multiple protrusions 23 and the multiple grooves 24 are disposed on the surface of the black matrix 16 on the color filter substrate 13 of the present embodiment, to enlarge the contact area between the color filter substrate 13 and the sealant 14, increase the adhesive strength between the color filter substrate 13 and the sealant 14, and more preferably, enlarge the contact area between the color filter substrate 13 and the sealant 14, change the shape of the contact surface between the color filter substrate 13 and the sealant 14, increase the peeling strength of the color filter substrate 13 and the thin film transistor array substrate 12, and avoid the problems of liquid crystal leakage and the like caused by the reason that the color filter substrate 13 and the sealant 14 are easy to peel at the same time.

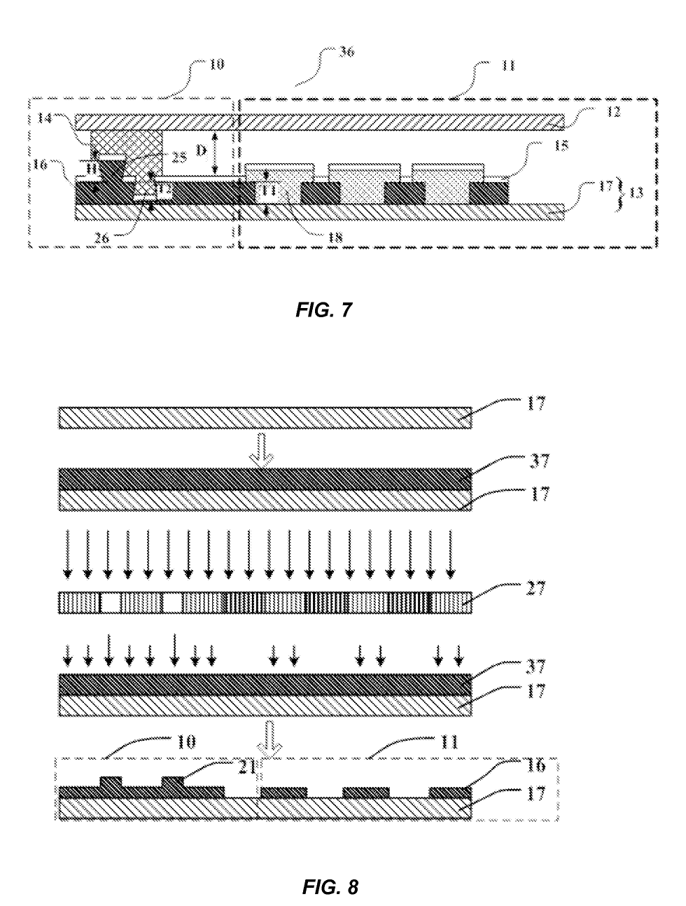

Please refer to FIG. 7. FIG. 7 is a simplified schematic diagram of a local section of a liquid crystal display panel including a color filter substrate where protrusions and grooves are disposed on the surface of a black matrix in a non-display area in another embodiment of the present invention. As shown in FIG. 7, the embodiment provides a liquid crystal display panel 36, which includes a display area 11 and a non-display area 10 on the periphery of the display area 11, and specifically includes: a color filter substrate 13; a thin film transistor array substrate 12, disposed opposite to the color filter substrate 13; a liquid crystal (not shown in the figure), sealed between the color filter substrate 13 and the thin film transistor array substrate 12; and a sealant 14, disposed in the non-display area 10 of the liquid crystal display panel 36 and between the thin film transistor array substrate 12 and the color filter substrate 13.

The color filter substrate 13 specifically includes: a substrate 17, including a display area 11 and a non-display area 10 on the periphery of the display area 11; a black matrix 16, disposed on the substrate 17, wherein the black matrix 16 in the display area 11 on the substrate 17 defines sub-pixels area, and multiple protrusions 25 and multiple grooves 26 are disposed on the surface of the black matrix 16 corresponding to the non-display area 10 on the substrate 17; a color filter pattern 18, disposed in the sub-pixels area defined by the black matrix in the display area 11; and an alignment layer (not shown in the figure).

The color filter substrate 13 also includes a common electrode layer 15 disposed on the black matrix 16 and the color filter pattern 18, but for a in-plane switching type liquid crystal display panel, a fringe-field switching liquid crystal display panel and the like, the common electrode layer does not need to be disposed on the color filter substrate, and this embodiment in which the common electrode layer 15 is disposed on the color filter substrate 13 is a preferred embodiment.

Multiple protrusions 25 and multiple grooves 26 are disposed on the black matrix 16 corresponding to the non-display area 10 on the substrate 17, may be disposed at equal intervals or disposed irregularly and may be equal or unequal in shape and size, and the specific arrangement mode and size of the multiple protrusions 25 and the multiple grooves 26 are not limited in this embodiment. In consideration of manufacturing difficulties, the multiple protrusions 25 and the multiple grooves 26 are disposed at equal intervals and are equal in shape and size as an example in this embodiment, so as to simplify the manufacturing procedures and improve the production efficiency. The height “H” of the highest position of each protrusion 25 may be smaller than or equal to the distance “D” between the color filter substrate 13 and the thin film transistor array substrate 12, and preferably in this embodiment, is smaller than the distance “D” between the color filter substrate 13 and the thin film transistor array substrate 12. The greatest longitudinal depth T2 of each groove 26 is smaller than or equal to the thickness T1 of the black matrix 16, and preferably in this embodiment, is smaller than the thickness T1 of the black matrix 16. The protrusions 25 and the grooves 26 may be in a single island shape, an end-to-end connected continuous shape, and a combination of island shape and end-to-end connected continuous shape, and the specific structures of the protrusions 25 and the grooves 26 can be in other shapes as well. The protrusions 25 and the grooves 26 may be spherical, conical, columnar, square, cubic, or in other irregular shapes, and the specific shapes of the protrusions 25 and the grooves 26 can be in other shapes as well. In consideration of enlarging the contact area between the sealant 14 and the common electrode layer 15, in a preferred embodiment, each protrusion 25 is in a big-end-up inverse cone shape, and each groove 26 is in a big-end-down cone. Compared with the structure shown in FIG. 6, the edge shape of each protrusion or groove with the same volume is changed from a vertical line to an oblique line, so as to further enlarge the contact area between the color filter substrate 13 and the sealant 14 and increase the adhesive strength between the color filter substrate 13 and the sealant 14. Meanwhile, as the protrusions 25 of the black matrix 16 or the sealant 14 are inversely conical, when the protrusions 25 are subjected to a peeling force in the vertical direction, the protrusions 25 and the grooves 26 form clamping structures, the bonding force between the black matrix 16 and the sealant 14 is strengthened on the basis of the above-mentioned embodiment, namely the peeling strength of the color filter substrate 13 and the thin film transistor array substrate 12 is increased, and the problems of liquid crystal leakage and the like caused by the reason that the color filter substrate 13 and the sealant 14 are easy to peel are avoided.

The liquid crystal display panel 36 also includes the sealant 14 disposed between the thin film transistor array substrate 12 and the color filter substrate 13 and located in the non-display area 10. The unprocessed sealant is liquid, and the liquid sealant is cured through ultraviolet after being filled in the whole sealant area of the non-display area 10 to form the sealant 14 with one protrusion and one groove. Of course, the sealant 14 may also form multiple grooves and multiple protrusions, in addition the multiple grooves and the multiple protrusions are matched with the multiple protrusions 25 and the multiple grooves 26 disposed on the black matrix 16 in the non-display area 10.

Please refer to FIG. 8. FIG. 8 is a simplified schematic diagram of a manufacturing process of a color filter substrate where protrusions are disposed on the surface of a black matrix in a non-display area in another embodiment of the present invention. As shown in FIG. 8, the present embodiment also provides a manufacturing process of the above-mentioned color filter substrate. The color filter substrate includes a display area and a non-display area on the periphery of the display area; a black matrix in the display area on the substrate defines sub-pixels area, and multiple protrusions are disposed on the surface of the black matrix in the non-display area on the color filter substrate; and a color filter pattern is disposed in the sub-pixels area. The specific manufacturing process for forming the multiple protrusions on the surface of the black matrix in the non-display area on the color filter substrate includes the following steps:
providing a substrate 17;
forming a light-tight negative photoresist layer 37 on the substrate 17, patterning the light-tight negative photoresist layer 37, and exposing and developing the light-tight negative photoresist layer 37 by adopting a half gray scale mask plate 27 when the light-tight negative photoresist layer 37 is patterned, so as to form in a display area 11 a black matrix 16 defining sub-pixels area and to form in a non-display area 10 a black matrix 16 including multiple protrusions 21 on the surface.

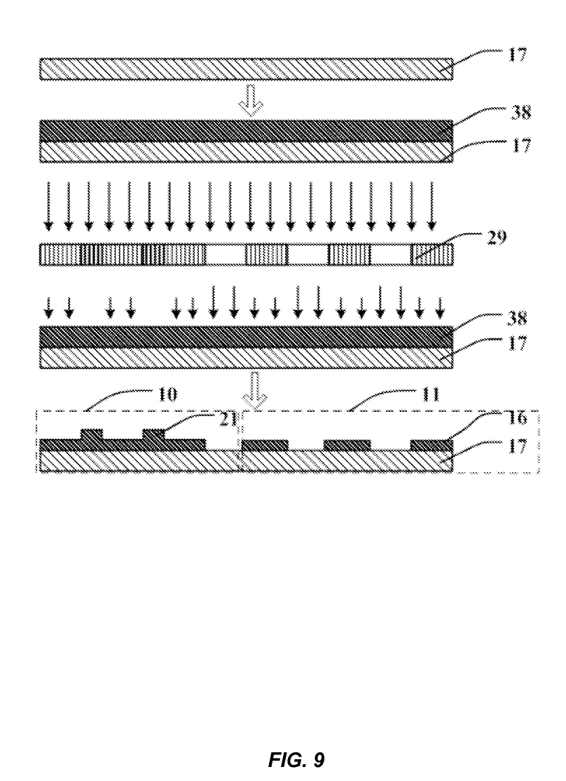

Please refer to FIG. 9. FIG. 9 is a simplified schematic diagram of a manufacturing process for a color filter substrate where protrusions are disposed on the surface of a black matrix in a non-display area in another embodiment of the present invention. As shown in FIG. 9, the embodiment also provides a manufacturing process for the above-mentioned color filter substrate. The color filter substrate includes a display area and a non-display area on the periphery of the display area; a black matrix in the display area on the substrate defines sub-pixels area, and multiple protrusions are disposed on the surface of the black matrix in the non-display area on the color filter substrate; and a color filter pattern is disposed in the sub-pixels area. The specific manufacturing process for forming the multiple protrusions on the surface of the black matrix in the non-display area on the color filter substrate includes the following steps:
providing a substrate 17;
forming a light-tight positive photoresist layer 38 on the substrate 17, patterning the light-tight positive photoresist layer 38, and exposing and developing the light-tight positive photoresist layer 38 by adopting a half gray scale mask plate 27 when the light-tight positive photoresist layer 38 is patterned, so as to form in a display area 11 a black matrix 16 defining sub-pixels area and to form in a non-display area 10 a black matrix 16 including multiple protrusions 21 on the surface.

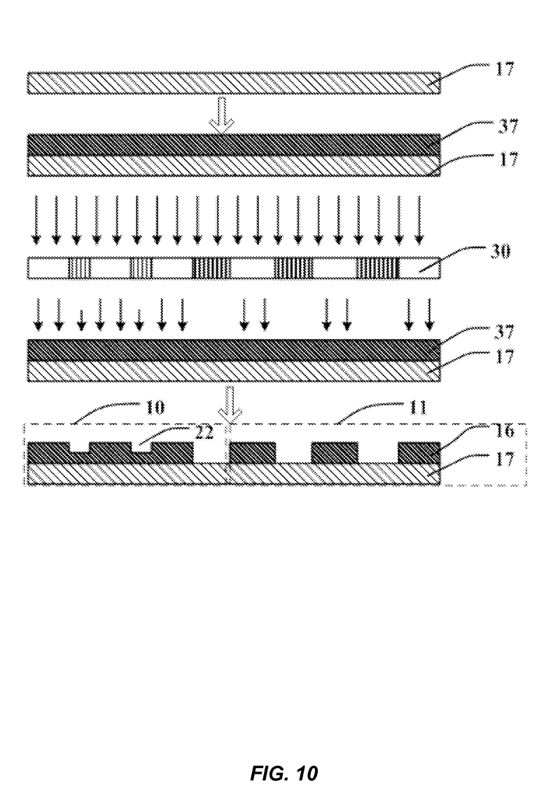

Please refer to FIG. 10. FIG. 10 is a simplified schematic diagram of a manufacturing process for a color filter substrate where grooves are disposed on the surface of a black matrix in a non-display area in another embodiment of the present invention. As shown in FIG. 10, the embodiment also provides a manufacturing process of the above-mentioned color filter substrate. The color filter substrate includes a display area and a non-display area on the periphery of the display area; a black matrix in the display area on the substrate defines sub-pixels area, and multiple grooves are disposed on the surface of the black matrix in the non-display area on the color filter substrate; and a color filter pattern is disposed in the sub-pixels area. The specific manufacturing process for forming the multiple grooves on the surface of the black matrix in the non-display area on the color filter substrate includes the following steps:
providing a substrate 17;
forming a light-tight negative photoresist layer 37 on the substrate 17, patterning the light-tight negative photoresist layer 37, and exposing and developing the light-tight negative photoresist layer 37 by adopting a half gray scale mask plate 27 when the light-tight negative photoresist layer 37 is patterned, so as to form in a display area 11 a black matrix 16 defining sub-pixels area and to form in a non-display area 10 a black matrix 16 including multiple grooves 22 on the surface.

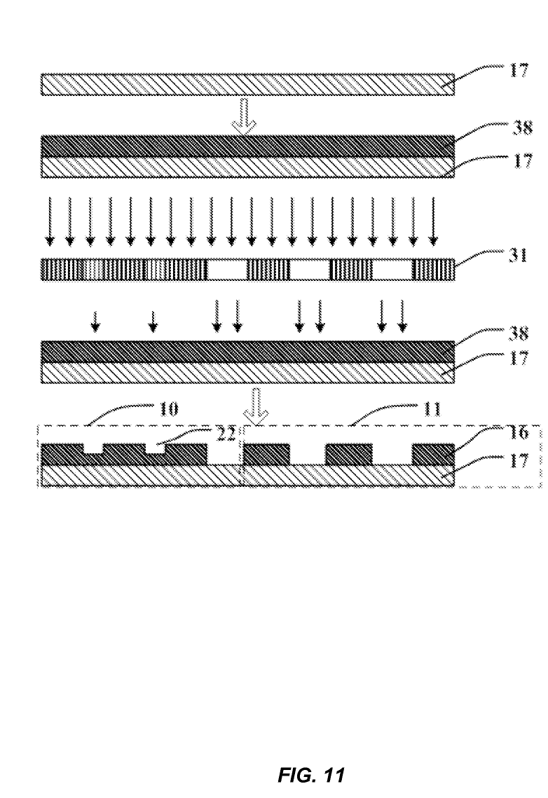

Please refer to FIG. 11. FIG. 11 is a simplified schematic diagram of a manufacturing process for a color filter substrate where grooves are disposed on the surface of a black matrix in a non-display area in another embodiment of the present invention. As shown in FIG. 11, the embodiment also provides a manufacturing process for the above-mentioned color filter substrate. The color filter substrate includes a display area and a non-display area on the periphery of the display area; a black matrix in the display area on the substrate defines sub-pixels area, and multiple grooves are disposed on the surface of the black matrix in the non-display area on the color filter substrate; and a color filter pattern is disposed in the sub-pixels area. The specific manufacturing process for forming the multiple grooves on the surface of the black matrix in the non-display area on the color filter substrate includes the following steps:
providing a substrate 17;
forming a light-tight positive photoresist layer 38 on the substrate 17, patterning the light-tight positive photoresist layer 38, and exposing and developing the light-tight positive photoresist layer 38 by adopting a half gray scale mask plate 27 when the light-tight positive photoresist layer 38 is patterned, so as to form in a display area 11 a black matrix 16 defining sub-pixels area and to form in a non-display area 10 a black matrix 16 including multiple grooves 22 on the surface.

It is to be appreciated that embodiments of the present invention can be implemented in various ways. Among other things, embodiments of the present invention provide a color filter substrate, a liquid crystal display panel including the color filter substrate, and a manufacturing process of the color filter substrate.

An embodiment of the present invention provides a color filter substrate, including: a substrate, including a display area and a non-display area on the periphery of the display area; and a black matrix, disposed on the substrate, wherein the black matrix corresponding to the non-display area on the substrate includes a non-flat surface.

According to an embodiment, the present invention also provides a liquid crystal display panel including the color filter substrate, and the liquid crystal display panel includes a display area and a non-display area on the periphery of the display area and includes: the above-mentioned color filter substrate; a thin film transistor array substrate, disposed opposite to the color filter substrate; and a liquid crystal, sealed between the color filter substrate and the thin film transistor array substrate.

According to an embodiment, the present invention also provides a manufacturing process of the color filter substrate, and the color filter substrate includes a display area and a non-display area on the periphery of the display area; a black matrix corresponding to the non-display area on the color filter substrate includes a non-flat surface; and the method includes the following steps: providing a substrate; and forming the black matrix with the non-flat surface in the non-display area on the substrate.

It is to be appreciated that embodiments of the present invention provide numerous advantages over existing techniques. In various embodiments, the present invention provide one or more protrusions or grooves disposed on the surface of the black matrix on the color filter substrate, which is to enlarge the contact area between the color filter substrate and a seal, thereby improving the adhesive strength between the color filter substrate and the seal, and more preferably, enlarge the contact area between the color filter substrate and the seal, change the shape of the contact surface between the color filter substrate and the seal, increase the peeling resistance, increase the peeling strength of the color filter substrate and the thin film transistor array substrate, avoid the problems of liquid crystal leakage and the like caused by the reason that the color filter substrate and the sealant are easy to peel, promote the quality of a product and improve the production efficiency at the same time. There are other benefits as well.

The above contents are made to further illustrate the present invention in detail in conjunction with the specific preferred embodiments, and the specific embodiments of the present invention cannot be considered as being merely limited to these illustrations. Multiple simple deductions or substitutions may be made by those of ordinary skills in the art without departing from the conception of the present invention, and should be within the protection scope of the present invention.

What is claimed is:

1. A color filter substrate, comprising:
a substrate, including a display area and a non-display area on periphery of the display area; and
a black matrix, disposed on the substrate, wherein the black matrix corresponding to the non-display area on the substrate includes a non-flat surface.

2. The color filter substrate according to claim 1, wherein at least one protrusion or at least one groove is disposed on the surface of the black matrix corresponding to the non-display area on the substrate.

3. The color filter substrate according to claim 1, wherein at least one protrusion and at least one groove are disposed on the surface of the black matrix corresponding to the non-display area on the substrate.

4. The color filter substrate according to claim 2, wherein protrusions or grooves are disposed at equal intervals or disposed irregularly.

5. The color filter substrate according to claim 3, wherein protrusions and grooves are disposed at equal intervals or disposed irregularly.

6. The color filter substrate according to claim 2, wherein the at least one protrusion or the at least one groove is spherical, conical, columnar, square, or cubic.

7. The color filter substrate according to claim 3, wherein the at least one protrusion and the at least one groove are spherical, conical, columnar, square, or cubic.

8. The color filter substrate according to claim 6, wherein shape and size of the protrusions or the grooves are equal or unequal.

9. The color filter substrate according to claim 7, wherein shape and size of the protrusions and the grooves are equal or unequal.

10. A liquid crystal display panel, including a display area and a non-display area on periphery of the display area, comprising:
the color filter substrate according to claims 1;
a thin film transistor array substrate, disposed opposite to the color filter substrate; and
a liquid crystal, sealed between the color filter substrate and the thin film transistor array substrate.

11. The liquid crystal display panel according to claim 10, further comprising a sealant disposed between the thin film transistor array substrate and the color filter substrate and located in the non-display area, wherein the sealant includes at least one protrusion additionally or alternatively at least one groove, and the at least one protrusion additionally or alternatively the at least one groove are matched with the black matrix in the non-display area.

12. The liquid crystal display panel according to claim 10, wherein a height of the highest position of each protrusion disposed on the black matrix corresponding to the non-display area on the color filter substrate is smaller than or equal to a distance between the color filter substrate and the thin film transistor array substrate.

13. The liquid crystal display panel according to claim 10, wherein the greatest longitudinal depth of each groove disposed in the black matrix corresponding to the non-display area on the color filter substrate is smaller than or equal to a thickness of the black matrix.

14. A manufacturing process of a color filter substrate, wherein the color filter substrate includes a display area and a non-display area on periphery of the display area and a black matrix corresponding to the non-display area on the color filter substrate includes a non-flat surface, the manufacturing process comprising following steps of:
providing a substrate; and
forming the black matrix with the non-flat surface in the non-display area on the substrate.

15. The manufacturing process of the color filter substrate according to claim 14, wherein a step of forming the black matrix with the non-flat surface in the non-display area on the substrate comprises: forming a light-tight photoresist layer on the substrate; and exposing and developing the light-tight photoresist layer by adopting a half gray scale mask plate.
